(19) United States
(12) Patent Application Publication
(10) Pub. No.: US 2025/0386648 A1
(43) Pub. Date: Dec. 18, 2025

(54) DISPLAY DEVICE AND ELECTRONIC DEVICE INCLDUING THE SAME

(71) Applicant: Samsung Display Co., Ltd., Yongin-si (KR)

(72) Inventors: HONGMIN YOON, Yongin-si (KR); YUJIN KIM, Yongin-si (KR); JUNGEUN PARK, Yongin-si (KR); HYUNBAE PARK, Yongin-si (KR); Hyelynn SONG, Yongin-si (KR); TAE WOO LIM, Yongin-si (KR)

(21) Appl. No.: 19/238,295

(22) Filed: Jun. 13, 2025

(30) Foreign Application Priority Data
Jun. 17, 2024 (KR) 10-2024-0078204

(51) Int. Cl. H10H 29/85; H10H 29/37; H10H 29/855

(52) U.S. Cl. CPC H10H 29/8517; H10H 29/37; H10H 29/855

(57) ABSTRACT

A display device includes: a display panel comprising a display area and a non-display area adjacent to the display area; a light control member on the display panel and comprising a plurality of light control units, a bank layer configured to distinguish the light control units from each other, and a spacer on the bank layer; and a color filter layer on the light control member and comprising a plurality of filter units each having a single color filter, a first area in which two color filters are laminated, and a second area in which three color filters are laminated, wherein the spacer overlaps the first area.

### CROSS-REFERENCE TO RELATED APPLICATION

The present application claims priority to and the benefit of Korean Patent Application No. 10-2024-0078204, filed on Jun. 17, 2024, in the Korean Intellectual Property Office, the entire disclosure of which is incorporated herein by reference.

### BACKGROUND

Aspects of some embodiments of the present disclosure herein relate to a display device, and an electronic device including the same.

A multi-media device of an electronic device, such as a television, a mobile phone, a tablet computer, a navigator, or a game console is provided with a display panel for displaying an image. The display panel may include a plurality of pixels for displaying images and each of the pixels may include a light-emitting element configured to generate light and a driving element connected to the light-emitting element.

A display device including a light transmission layer and a light conversion layer may desirably have high visibility and color purity to relatively improve the display quality of the display device. Accordingly, the display device may be manufactured by bonding a substrate provided with a light-emitting element with a substrate provided with a light conversion layer. However, defects may result due to substrate-bonding processes.

The above information disclosed in this Background section is only for enhancement of understanding of the background and therefore the information discussed in this Background section does not necessarily constitute prior art.

### SUMMARY

Aspects of some embodiments of the present disclosure include a display device that may be suitable for relatively easy manufacturing, and an electronic device including the display device.

Aspects of some embodiments of the present disclosure include a display device including, a display panel including a display area and a non-display area adjacent to the display area, a light control member on the display panel and including a plurality of light control units, a bank layer configured to distinguish the light control units from each other, and a spacer on the bank layer, and a color filter layer on the light control member and including a plurality of filter units each having a single color filter, a first area in which two color filters are laminated, and a second area in which three color filters are laminated, wherein the spacer may overlap the first area.

According to some embodiments of the present disclosure, a display device includes a display panel including a display area and a non-display area adjacent to the display area, a light control member on the display panel and including a plurality of light control units and a bank layer configured to distinguish the light control units from each other, and a color filter layer on the light control member and including a plurality of filter units each having a single color filter, a first area in which two color filters are laminated, and a second area in which three color filters are laminated, wherein a bottom surface of the second area facing the display panel may be more adjacent (or closer) to the display panel than a bottom surface of the first area facing the display panel.

According to some embodiments of the present disclosure, an electronic device includes a display device, the display device comprising, a display panel including a display area and a non-display area adjacent to the display area, a light control member on the display panel and including a plurality of light control units, a bank layer configured to distinguish the light control units from each other, and a spacer on the bank layer, and a color filter layer on the light control member and including a plurality of filter units each having a single color filter, a first area in which two color filters are laminated, and a second area in which three color filters are laminated, wherein the spacer may overlap the first area.

### BRIEF DESCRIPTION OF THE DRAWINGS

The accompanying drawings are included to provide a further understanding of aspects of some embodiments of the present disclosure, and are incorporated in and constitute a part of this specification. The drawings illustrate aspects of some embodiments of the present disclosure and, together with the description, serve to explain principles of embodiments according to the present disclosure. In the drawings:

FIG. 1 is a perspective view of a display device DD according to some embodiments of the present disclosure;

FIG. 2 is a cross-sectional view of the display device DD according to some embodiments of the present disclosure;

FIG. 3 is a plan view of a display panel DP according to some embodiments of the present disclosure;

FIG. 4 is an enlarged plan view of a display area according to some embodiments of the present disclosure;

FIG. 5 is a cross-sectional view of a display panel according to some embodiments of the present disclosure;

FIG. 6 is a cross-sectional view of the display device corresponding to line II-II′ illustrated in FIG. 5;

FIG. 7A is a cross-sectional view of a portion corresponding to line I-I′ illustrated in FIG. 1 and FIG. 7B is an enlarged view of the area AA′ area illustrated in FIG. 7A;

FIG. 8 is a cross-sectional view of a display device according to some embodiments of the present disclosure;

FIG. 9 is a cross-sectional view of a display device according to some embodiments of the present disclosure;

FIG. 10 is is a block diagram illustrating an electronic device according to an embodiment of the present disclosure; and

FIG. 11 is a schematic view of electronic devices according to embodiments of the present disclosure.

### DETAILED DESCRIPTION

It will be understood that when an element or layer is referred to as being “on”, “connected to” or “coupled to” another element or layer, it can be directly on, connected or coupled to the other element or intervening third elements may be present.

Like reference numerals in the drawings refer to like elements. In addition, in the drawings, the thickness and the ratio and the dimension of the element are exaggerated for effective description of the technical contents. The term “and/or” includes any and all combinations of one or more of the associated items.

Terms such as first, second and the like may be used to describe various components, but these components should not be limited by the terms. Such terms are only used for distinguishing one element from other elements. For instance, a first component may be referred to as a second component, or similarly, a second component may be referred to as a first component, without departing from the scope of the present disclosure. The singular expressions include plural expressions unless the context clearly dictates otherwise.

In addition, the terms such as “under”, “lower”, “on” and “upper” are used for explaining associations of items illustrated in the drawings. The terms are used as a relative concept and are described with reference to the direction indicated in the drawings.

It should be understood that the terms “comprise” or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which example embodiments belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to the accompanying drawings.

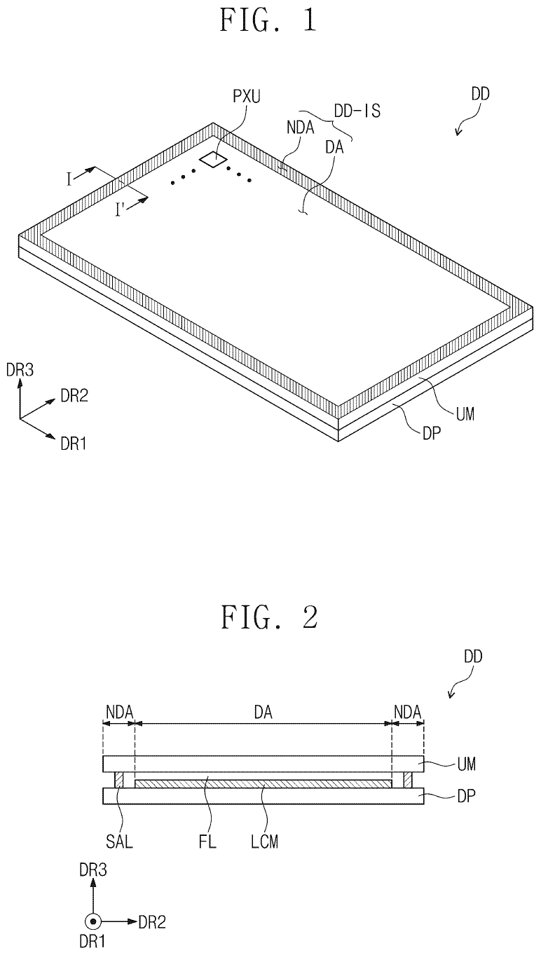

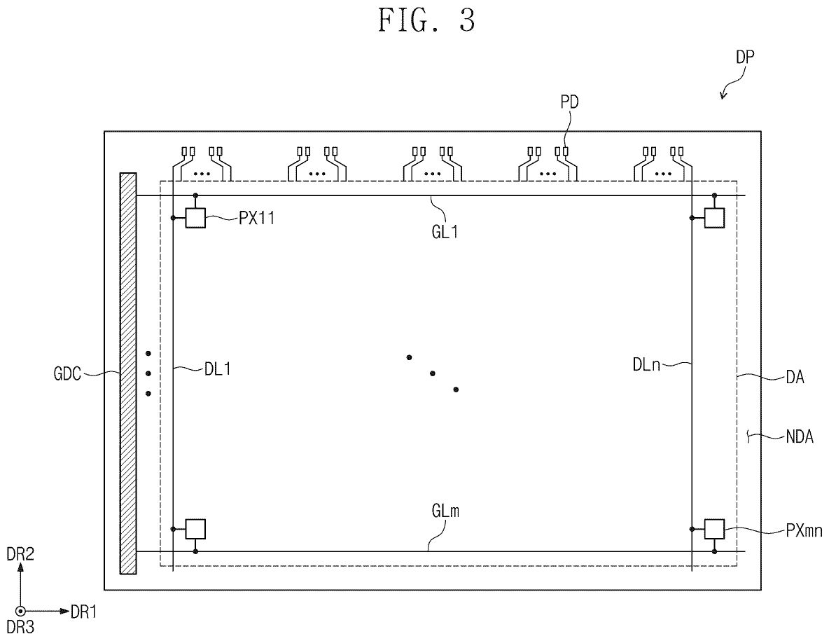

FIG. 1 is a perspective view of a display device according to some embodiments of the present disclosure. FIG. 2 is a cross-sectional view of a display device according to some embodiments of the present disclosure.

Referring to FIG. 1, the display device DD may be activated in response to an electrical signal to display images. The display device DD may include various embodiments configured to provide images to various users. For example, the display device DD may be a small or medium-sized device such as a monitor, a mobile phone, a tablet computer, a navigator, a game console or the like as well as a large-scale device such as a television, an external billboard or the like. However, the examples of the display device DD are merely illustrative and are not limited to any one as long as they do not depart from the spirit and scope of embodiments according to the present disclosure.

The display device DD may have in a plan view a rectangular shape of short sides extending in the first direction DR1 and long sides extending in the second direction DR2 crossing the first direction DR1. However, the embodiments according to the present disclosure are not limited thereto and the display device DD may have various shapes such as circular or polygonal shapes.

Hereinafter, a direction, which vertically crosses (or substantially vertically crosses) the plane defined by the first and second directions DR1 and DR2, is defined as a third direction DR3. In the specification, “when viewed in a plan view” may mean a state of being viewed from a third direction DR3 toward the display device DD. In the specification, the expression “in a cross-sectional view” may mean a state of being viewed in the first direction DR1 or the second direction DR2.

The display device DD may display an image via a display surface DD-IS parallel to a surface defined by the first direction DR1 and the second direction DR2. The display surface DD-IS may be parallel to a surface defined by the first direction DR1 and the second direction DR2. The top surface of a member located on the uppermost side of the display device DD with respect to the third direction DR3 may be defined as the display surface DD-IS.

The normal direction of the display surface DD-IS, namely, the thickness direction of the display device DD may indicate the third direction DR3. The front surfaces (or top surfaces) and the rear surfaces (or bottom surfaces) of respective layers or units to be described below are distinguished from each other by the third direction DR3.

The display device DD may include a display area DA and a non-display area NDA. The display area DA includes unit pixels PXU located therein, and the non- display area NDA does not include the unit pixels PXU. The non-active area NDA may be defined along the edge (e.g., in a periphery or outside a footprint) of the display surface DD-IS. The non-display area NDA may surround the display area DA. The non-display area NDA according to some embodiments of the present disclosure may be omitted or located only in one side of the display area DA. FIG. 1A illustrates an example planar display device DD, but the display device DD may have a curved shape, or be foldable or rollable, or be slidable from the housing.

The unit pixels PXU shown in FIG. 1A may define pixel rows and pixel columns. The unit pixel PXU is a minimum repeatable unit and may include at least one pixel. The unit pixels PXU may include a plurality of pixels providing light beams of different colors.

Referring to FIG. 2, the display device DD may include a display panel DP, a light control member LCM, a filling member FL, a plurality of sealing members SAL and a color filter panel UM. The display panel DP may be referred to as a bottom display substrate and the color filter panel UM may be referred to as a top display substrate.

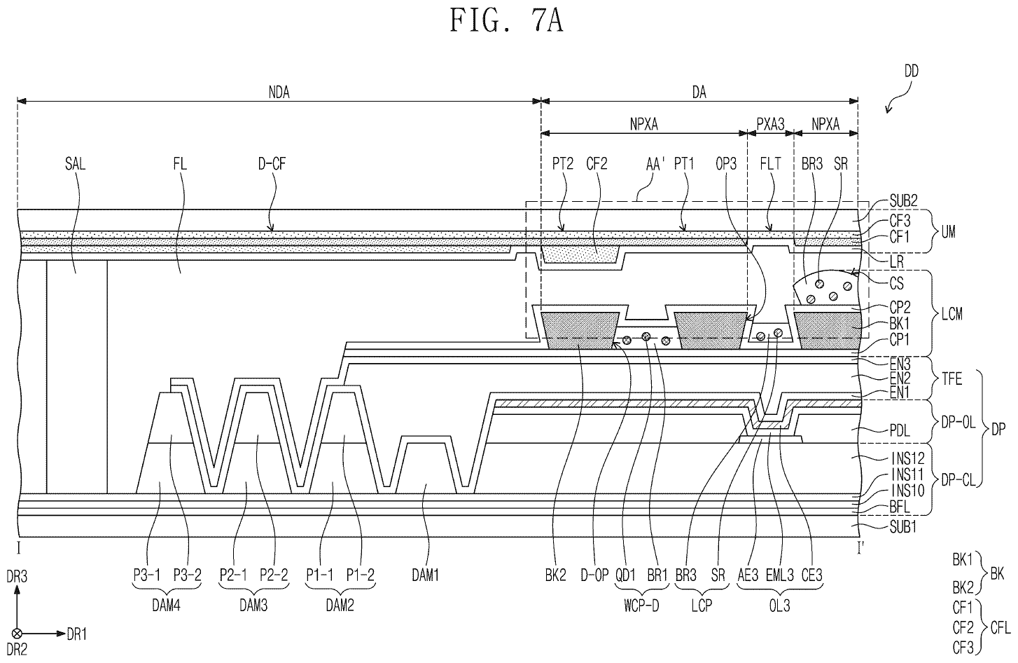

The light control member LCM may be located on the display panel DP. The light control member LCM may be arranged to overlap the display area DA and include a light transmission layer LCP (see FIG. 6) and light conversion layers WCP (see FIG. 6) configured to convert optical properties of source light (or first color light) provided by the light-emitting element. The light control member LCM may selectively convert or transmit the color of the source light.

The color filter panel UM may be located on the display panel DP and the light control member LCM. The color filter panel UM may be opposite to and spaced apart from the display panel DP. The color filter panel UM may overlap the display area DA and transmit light selectively converted or transmitted by the light control member LCM. The color filter panel UM may absorb light, which was not converted by but passed through the light control member LCM, to prevent the color purity of the display device DD (see FIG. 1) from being reduced.

The sealing member SAL may be located between the display panel DP and the color filter panel UM. The sealing member SAL may bond the display panel DP and the color filter panel UM to each other. The sealing member SAL may be arranged to overlap the non-display area NDA.

A prescribed cell gap may be provided between the display panel DP and the color filter panel UM. The cell gap may be maintained by the sealing member SAL combining the display panel DP and the color filter panel UM.

The sealing member SAL may include a binder resin and inorganic fillers mixed with the binder resin. The sealing member SAL may include other additive agents. The additive agents may include amine-based curing agents and photoinitiators. The additive agents may further include silane-based additive agents and acrylic-based additive agents. The sealing member SAL may also include an inorganic-based material such as frit.

The filling member FL may be located between the display panel DP and the color filter panel UM to fill a vacant space between the display panel DP overlapping the display area DA and the color filter panel UM. The filling member FL may include silicon, epoxy and an acrylic-based heat curable material. However, the material of the filling member FL is not limited thereto.

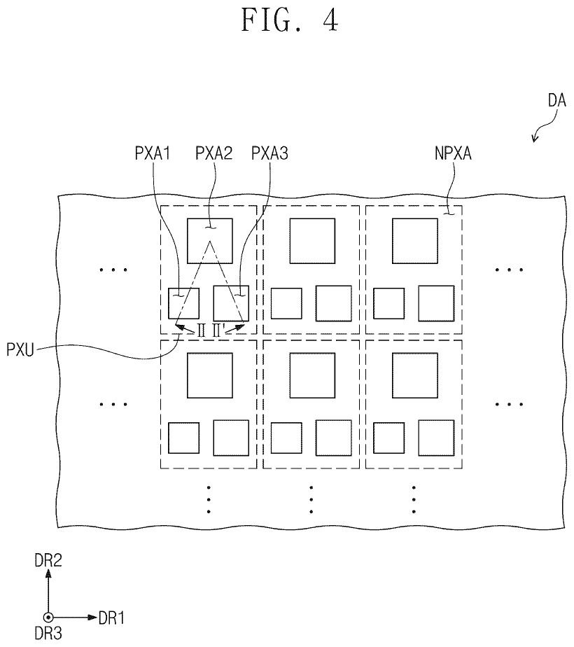

FIG. 3 is a plan view of the display panel DP according to some embodiments of the present disclosure.

FIG. 3 illustrates a planar arrangement of signal lines GL1 to GLm and DL1 to DLn and pixels PX11 to PXmn. The signal lines GL1 to GLm and DL1 to DLn may include a plurality of gate lines GL1 to GLm and a plurality of data lines DL1 to DLn.

Each of the pixels PX11 to PXnm may be connected to a corresponding gate line among the plurality of gate lines GL1 to GLn and a corresponding data line among the plurality of data lines DL1 to DLm. Each of the pixels PX11 to PXnm may include a pixel driving circuit and a light emitting element. According to the configuration of the pixel driving circuit of the pixels PX11 to PXmn, more various kinds of signal lines may be provided to the display panel DP.

A gate driving circuit GDC may be integrated to the display panel DP through an oxide silicon gate driver circuit (OSG) process or an amorphous silicon gate driver circuit (ASG) process. The gate driving circuit GDC connected to the gate lines GL1 to GLm may be located at one side of the non-display area BDA in the first direction DR1. Pads PD connected to the terminals of the plurality of data lines DL1 to DLn may be located at one side of the non-display area BDA in the second direction DR2.

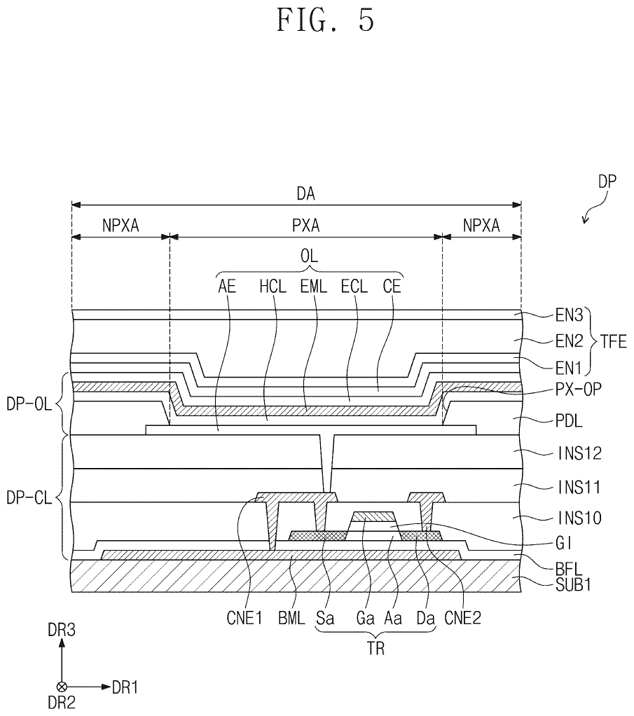

FIG. 4 is an enlarged plan view of the display area according to some embodiments of the present disclosure.

Referring to FIG. 4, the display area DA may include a plurality of unit pixels PXU. The unit pixels PXU may be arranged in the first direction DR1 and the second direction DR2. By way of example, FIG. 4 illustrates 6 unit pixels PXU, but the number of unit pixels PXU may not be limited thereto. Hereinafter, any one of the plurality of unit pixels PXU will be described.

The unit pixel PXU may include emission areas PXA1, PXA2 and PXA3 and a non-emission area NPXA surrounding the emission areas PXA1, PXA2 and PXA3. FIG. 4 shows an example shape of the emission areas PXA1, PXA2 and PXA3.

The emission areas PXA1, PXA2 and PXA3 may correspond to areas from which light provided from the light-emitting element is output. The emission areas PXA1, PXA2, PXA3 may include a first emission area PXA1, a second emission area PXA2 and a third emission area PXA3. The first to third emission areas PXA1, PXA2 and PXA3 may be distinguished from each other depending on the color of the light output towards outside the display device DD (see FIG. 1). The non-emission area

NPXA may set the boundaries of the first to third pixel areas PXA1, PXA2 and PXA3 and prevent or reduce color mixture between the first to third emission areas PXA1, PXA2 and PXA3.

One of the first to third emission areas PXA1, PXA2 and PXA3 provides first color light corresponding to source light provided from the light-emitting element, another one provides second color light different from the first color light, and the remaining one provides third color light different from the first color light and the second color light. For example, the first color light may be blue light, the second color light may be red light, and the third color light may be green light. However, the example color light is not necessarily limited thereto.

According to some embodiments, each of the first to third emission areas PXA1, PXA2 and PXA3 may have the same shape in a plan view, have different planar areas.

The second emission areas PXA2 arranged along the first direction DR1 may be defined to be a first row, and the first and third emission areas PXA1 and PXA3 arranged along the first direction DR1 may be defined to be a second row. In the second row, the first and third emission areas PXA1 and PXA3 may be alternately arranged along the first direction DR1.

The first row including the second emission areas PXA2 may be provided in plural to be arranged along the first direction DR1, and the second row may also be provided in plural to be arranged along the first direction DR1. As shown in FIG. 4, the first rows and the second rows may be alternately arranged along the second direction DR2.

Each of the first to third emission areas PXA1, PXA2 and PXA3 may have a rectangular shape and the planar areas of the first to third emission areas PXA1, PXA2 and PXA3 may be different from each other. By way of example, FIG. 4 shows the first to third emission areas PXA1, PXA2 and PXA3 each having right angle corners, but the example is not limited thereto. The first to third emission areas PXA1, PXA2 and PXA3 may have round (or substantially round) corners.

By way of example, when viewed in a plan view, the area of the second emission areas PXA2 may be greater than those of the first and third emission areas PXA1 and PXA3. When viewed in a plan view, the first emission area PXA1 may have a greater area than the third emission area PXA3. In other words, the second emission area PXA2 may have the greatest area and the third emission area PXA3 may have the smallest area.

Meanwhile, the arrangement type of the first to third emission areas PXA1, PXA2 and PXA3 shown in FIG. 4 is illustrative rather than restrictive and may vary depending on the design of the display device DD (see FIG. 1). The shape, area, arrangement or the like of the emission areas may be differently designed in various ways, depending on the color light extraction efficiency and are not limited to the embodiments of FIG. 4.

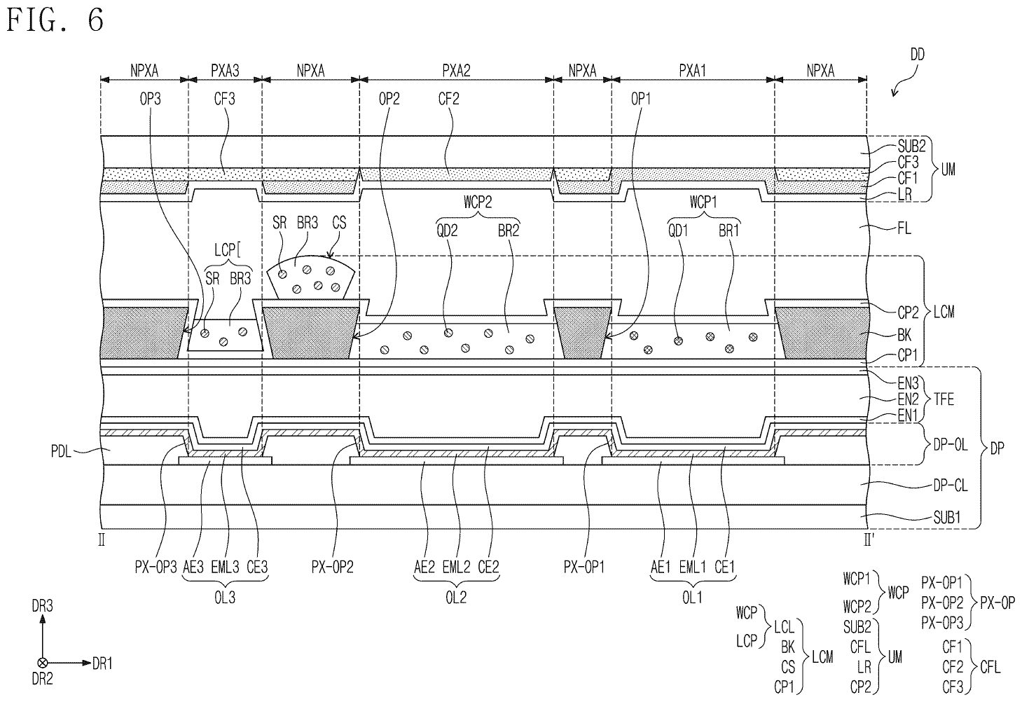

FIG. 5 is a cross-sectional view of a display panel according to some embodiments of the present disclosure.

By way of example, the emission area PXA illustrated in FIG. 5 may be any one of the first to third emission areas PXA1, PXA2 and PXA3 illustrated in FIG. 4.

Referring to FIG. 5, the display panel DP may include a first base substrate SUB1 (or the bottom substrate), a circuit layer DP-CL, a light emitting element layer DP-OL and an encapsulation layer TFE.

The circuit layer DP-CL may further include insulation layers, a semiconductor pattern, a conductive pattern, signal lines or the like. In manufacturing the display panel DP, the insulation layers, a semiconductor layer and a conductive layer may be provided on the first base substrate SUB1 through processes of coating, deposition and the like. Then, the insulation layers, the semiconductor layer and the conductive layer may be optionally patterned through photolithography processes.

Through these processes, the semiconductor pattern, conductive pattern, signal lines or the like included in the display panel DP may be provided.

Each of the pixels may have an equivalent circuit including transistors, at least one capacitor and a light-emitting element, and the equivalent circuit of the pixel may be modified in various types. The semiconductor pattern may be arranged in a prescribed rule across pixels depending on the equivalent circuit diagram. In FIG. 5, one transistor TR and a light-emitting element OL included in the pixel are illustrated by way of an example.

The first base substrate SUB1 may provide a base surface on which the circuit layer DP-CL is to be provided. The first base substrate SUB1 may have a single layer or multilayer structure. For example, the first base substrate SUB1 of a multilayer structure may include synthetic resin layers and at least one inorganic layer located therebetween, or a glass substrate and a synthetic resin layer located thereon.

The synthetic resin layer included in the first base substrate SUB1 may include at least one among an acrylic-based resin, a methacrylic-based resin, polyisoprene, a vinyl-based resin, an epoxy-based resin, a urethane-based resin, a cellulose-based resin, a siloxane-based resin, a polyamide-based resin, a parylene- based resin, or a polyimide-based resin. However, the material of the first base substrate SUB1 is not limited thereto.

The circuit layer DP-CL may be located on the first substrate SUB1. The circuit layer DP-CL may include at least one insulation layer, a semiconductor pattern and a conductive pattern. Meanwhile, a laminate structure of the circuit layer DP-CL may be modified in various ways depending on the manufacturing process of the circuit layer DL-CL or the configuration of elements included in the pixel. FIG. 5 shows the laminate type of an example circuit layer DP-CL. However, this is merely illustrative and is not limited to any one embodiment as long as the circuit layer DP-CL includes driving elements configured to drive the pixel.

The circuit layer DP-CL may include a light-shielding pattern BML, a transistor TR, connection electrodes CNE1 and CNE2, an insulation pattern GI and a plurality of insulation layers INS10, INS11 and INS12.

The light-shielding pattern BML may be located on the first base substrate SUB1. The light-shielding pattern BML may overlap the transistor TR. The light-shielding layer BML may prevent or reduce visibility of the conductive patterns included in the circuit layer DP-CL through external light, or prevent or reduce damage to a semiconductor layer included in the transistor TR by external light.

A buffer layer BFL may be located on the first base substrate SUB1 so as to cover a portion of the light-shielding pattern BML. The buffer layer BFL may have a contact hole defined therein and configured to expose a portion of the light-shielding pattern BML. The buffer layer BFL may relatively improve the bonding force between the first base substrate SUB1 and the semiconductor pattern.

The buffer layer BFL may include an inorganic material. For example, the buffer layer BFL may include at least one among aluminum oxide, titanium oxide, silicon oxide, silicon nitride, silicon oxynitride, zirconium oxide, or hafnium oxide. However, the material of the buffer layer BFL is not limited thereto.

The semiconductor pattern of the transistor TR may be located on the buffer layer BFL. The semiconductor pattern may include polysilicon. However, the embodiments according to the present disclosure are not limited thereto and the semiconductor pattern may include amorphous silicon, crystalline oxide, or an amorphous oxide.

A source area Sa, a drain area Da and a channel area Aa of the transistor TR may be provided from the semiconductor pattern. The semiconductor pattern may be divided into a plurality of areas, depending on the conductivity. For example, the semiconductor pattern may have different electric property depending on doping or reduction of a metal oxide. A high conductivity area in the semiconductor pattern may serve as an electrode or a signal line, which may correspond to the source area Sa and drain area Da of the transistor TR. A non-doped or non-reduced area having a relatively low conductivity may correspond to the channel area (or an active area) of the transistor TR.

The insulation layer may be provided on the semiconductor pattern of the transistor, and then be patterned to provide an insulation pattern GI. A gate electrode Ga may be located on the insulation pattern GI. The gate electrode Ga may be used as a mask in processes for providing the insulation pattern GI. The gate electrode Ga may overlap the channel area Aa, and be spaced apart from the semiconductor pattern of the transistor TR with the insulation pattern GI interposed therebetween in a cross-sectional view.

The plurality of insulation patterns INS10, INS11 and INS12 may be located on the buffer layer BFL. The plurality of insulation layers INS10, INS11 and INS12 each may include at least one inorganic layer or organic layer. For example, the inorganic layer of the insulation layers INS10, INS11 and INS12 may include at least one among aluminum oxide, titanium oxide, silicon oxide, silicon nitride, silicon oxynitride, zirconium oxide, or hafnium oxide, but is not limited thereto. The organic layer of the insulation layers INS10, INS11 and INS12 may include at least one among phenolic polymer, acrylic polymer, imide-based polymer, aryl ether-based polymer, amide-based polymer, fluorine-based polymer, p-xylene-based polymer, vinyl alcohol-based polymer, or a polymer containing a combination thereof, but is not limited thereto.

The first insulation layer INS10 may be located on the buffer layer BFL and cover the gate electrode Ga. The first insulation layer INS10 may have a contact hole defined therein and configured to expose a portion of the semiconductor pattern of the transistor TR.

The connection electrodes CNE1 and CNE2 may include a first connection electrode CNE1 and second connection electrode CNE2 located on the first insulation layer INS10. The first connection electrode CNE1 may be connected to the source area Sa of the transistor TR through the contact hole penetrating through the first insulation layer INS10. According to some embodiments, the first connection electrode CNE1 may be connected to the light shielding pattern BML through the contact hole penetrating the first insulation layer INS10 and the buffer layer BFL. The second connection electrode CNE2 may be connected to the drain area Da of the transistor TR through the contact hole penetrating through the first insulation layer INS10. The second connection electrode CNE2 may extend in a plan view to be connected to another transistor or wiring.

The second insulation layer INS11 and the third insulation layer INS12 may be located on the first insulation layer INS10 to cover the connection electrodes CNE1 and CNE2. The second insulation layer INS11 and the third insulation layer INS12 may have a penetration hole defined therein and configured to expose a portion of the first connection electrode CNE1, and the first connection electrode CNE1 may be connected to a first electrode AE of the light-emitting element OL located on the third insulation layer INS12. According to some embodiments, the third insulation layer INS12 may include an organic layer to provide the flat top surface. However the embodiments according to the present disclosure are not limited thereto.

The light-emitting element layer DP-OL may be located on the circuit layer DP-CL. The light-emitting element layer DP-OL may include a plurality of light-emitting elements OL and a pixel definition layer PDL. FIG. 5 illustrates a cross section corresponding to one of the plurality of light-emitting elements OL. The light-emitting element OL may be defined with a hole control layer HCL portion, a light-emitting layer EML portion, an electron control layer ECL portion, and a second electrode CE portion that are located on an emission opening PX-OP to be described below.

The display area DA may include the emission area PXA corresponding to the light-emitting element OL and the non-emission area NPXA surrounding the emission area PXA. The light-emitting element OL may include the first electrode AE, the hole control layer HCL, the light-emitting layer EML, the electron control layer ECL, and the second electrode CE.

The first electrode AE may be located on the top surface of the third insulation layer INS12. The first electrode AE may be connected to the first connection electrode CNE1 through a penetration hole penetrating through the second and third insulation layers INS11 and INS12.

The pixel definition layer PDL may be located on the third insulation layer INS12. The pixel definition layer PDL may have the emission opening PX-OP defined therein and configured to expose a portion of the first electrode AE. The pixel definition layer PDL may cover a portion of the top surface of the first electrode AE. According to some embodiments, the portion of the first electrode AE exposed by the emission opening PX-OP may correspond to the emission area PXA. An area in which the pixel definition layer PDL is located may correspond to the non-emission area NPXA surrounding the emission area PXA.

Meanwhile, according to some embodiments, the pixel definition layers PDL may include a light absorption material. The pixel definition layer PDL may include a black coloring agent. The black coloring agent may include a block dye or a black pigment. The black coloring agent may include carbon black, a metal such as chromium or an oxide thereof. However, the embodiments of the pixel definition layer PDL are not limited thereto.

The hole control layer HCL may be located on the first electrode AE and the pixel definition layer PDL. The hole control layer HCL may be arranged in common in the plurality of pixels. A portion of the hole control layer HCL may be located in the emission opening PX-OP. The hole control layer HCL may overlap the emission area PXA and the non-emission area NPXA. The hole control layer HCL may include at least one of the hole transport layer or a hole injection layer.

The emission layer EML may be located on the hole control layer HCL. The hole control layer EML may be arranged in common in the plurality of pixels. A portion of the emission layer EML may be located in the emission opening PX-OP and overlap the emission area PXA. The emission layer EML may overlap the emission area PXA and the non-emission area NPXA.

The emission layer EML may include an organic emission material, an inorganic emission material, quantum dots, or quantum rods. The emission layer EML may be divided corresponding to each pixel and provided in an emission pattern. However, the embodiments according to the present disclosure are not limited thereto, and the emission layer EML may be provided as a common layer to be provided in common to the pixels. The emission layer EML may generate first light as source light. For example, the first light may be blue light, but is not limited thereto.

According to some embodiments, the light-emitting element OL may have a tandem structure including a plurality of emission layers. The plurality of emission layers may be laminated on the first electrode AE along the thickness direction. A portion of the plurality of emission layers may generate the same (or substantially the same) color light, the other may generate different color light. For example, the light-emitting element OL according to some embodiments may include four emission layers, and three of the four emission layers may generate blue light and one emission layer may generate green light. However, this is merely an example, and the structure of the emission layer EML is not necessarily limited thereto. The light-emitting element of the tandem structure may further include function layers such as a hole control layer, an electron control layer, and a charge generation layers located between the plurality of emission layers.

The electron control layer ECL may be located on the emission layer EML. The electron control layer ECL may be arranged in common in the plurality of pixels. A portion of the electron control layer ECL may be located in the emission opening PX-OP. The electron control layer ECL may overlap the emission area PXA and the non-emission area NPXA. The electron control layer ECL may include at least one of an electron transport layer or an electron injection layer.

The second electrode CE may be located on the electron control layer ECL. The second electrode CE may be arranged in common in the plurality of pixels. The second electrode CE may overlap the emission area PXA and the non-emission area NPXA. The second electrode CE may be provided with a common voltage, and be referred to as a common electrode.

The first voltage may be applied to the first electrode AE, and the second voltage may be applied to the second electrode CE via the transistor TR. Holes and electrons injected to the light emitting layer EML may be combined to form excitons, and the light emitting element OL may emit light while the excitons are transitioned to the ground state.

The encapsulation layer TFE may be located on the light-emitting element layer DP-OL to encapsulate the light-emitting element layer DP-OL. The encapsulation layer TFE may include first to third encapsulation layers EN1, EN2, and EN3. The first encapsulation layer EN1 may be located on the second electrode CE, and the second and third encapsulation layers EN2 and EN3 may be sequentially arranged on the first encapsulation layer EN1.

According to some embodiments, the first and third encapsulation layers EN1 and EN3 may include an inorganic layer capable of protecting the light-emitting element layer DP-OL from moisture and/or oxygen. For example, the inorganic layer may include at least one among aluminum oxide, titanium oxide, silicon oxide, silicon nitride, silicon oxynitride, zirconium oxide, or hafnium oxide, but is not limited thereto.

According to some embodiments, the second encapsulation layer EN2 may include an organic layer capable of protecting the light-emitting element layer DP-OL from a foreign matter such as dust particles. For example, the organic layer may include an acrylic-based resin, but is not limited thereto.

FIG. 6 is a cross-sectional view of the display device corresponding to (e.g., along) the line II-II′ illustrated in FIG. 5.

By way of example, the circuit layer DP-CL is simply shown as one layer.

By way of example, the hole control layer HCL (see FIG. 5) and the electron control layer ECL (see FIG. 5) of the light-emitting elements OL are omitted.

Overlapping descriptions of components shown in FIG. 6, corresponding to those described with reference to the above drawings, may be omitted or simplified.

Referring to FIG. 6, the emission opening PX-OP may be defined by the pixel definition layer PDL. The emission opening PX-OP may include a first emission opening PX-OP1, a second emission opening PX-OP2, and a third emission opening PX-OP3.

The first emission opening PX-OP1 may overlap the the first emission area PXA1. The second emission opening PX-OP2 may overlap the the second emission area PXA2. The third emission opening PX-OP3 may overlap the the third emission area PXA3.

The length of the third emission opening PX-OP3 in the first direction DR1 may be smaller than those of the first and second emission openings PX-OP1 and PX-OP2 in the first direction DR1. The length of the first emission opening PX-OP1 in the first direction DR1 may be smaller than that of the second emission opening PX-OP2 in the first direction DR1.

The light-emitting elements OL1, OL2 and OL3 may include a first light-emitting element OL1, a second light-emitting element OL2 and a third light-emitting element OL3. The first light-emitting element OL1 may be located in the first emission opening PX-OP1 and overlap the first emission area PXA1. The second light-emitting element OL2 may be located in the second emission opening PX-OP2 and overlap the second emission area PXA2. The third light-emitting element OL3 may be located in the third emission opening PX-OP3 and overlap the third emission area PXA3.

The first to third light-emitting elements OL1, OL2 and OL3 may respectively include the first electrodes AE1, AE2 and AE3, the light emitting layers EML1, EML2 and EML3, and the second electrodes CE1, CE2 and CE3.

The first electrodes AE1, AE2 and AE3 of the first to third light-emitting elements OL1, OL2 and OL3 may be spaced apart from each other on the circuit element layer DP-CL. According to some embodiments, the first electrodes AE1, AE2 and AE3 of the first to third light-emitting elements OL1, OL2 and OL3 may be respectively connected to corresponding transistors of the circuit layer DP-CL. The first electrodes AE1, AE2 and AE3 may be connected to other transistors and at least one capacitor via transistors directly connected thereto.

The encapsulation layer TFE may be located on the top surface of the light-emitting element layer DP-OL. The encapsulation layer TFE may include first to third encapsulation layers EN1, EN2 and EN3. The encapsulation layer TFE is described in detail with reference to FIG. 5 and thus description thereof will be omitted.

The light control member LCM may be located on the display panel DP. The light control member LCM may be located on the top surface of the encapsulation layer TFE. The light control member LCM may be located on the top surface of the third encapsulation layer EN3.

The light control member LCM may include a first capping layer CP1, a bank layer BK, a light control units LCL, a second capping layer CP, and a spacer CS. The first capping layer CP1 may be located on the top surface of the encapsulation layer TFE. The first capping layer CP1 may be located on the top surface of the third encapsulation layer EN3. The first capping layer CP1 may cover the bottom surfaces of the bank layer BK and the light control units LCL.

The bank layer BK may be located on the top surface of the first capping layer CP1. The bank layer BK may overlap the non-display area NPXA. The light control units LCL may be distinguished from each other by the bank layer BK. When viewed in the second direction DR2, a plurality of the bank layers BK are shown, but the bank layer BK may be integrated (or substantially integrated) to each other.

The bank layer BK may include a black pigment and hydrophobic materials. The bank layer BK includes a black pigment and accordingly may have black color.

Therefore, the bank layer BK may block light so that the light beams emitted from the light-emitting elements OL1, OL2 and OL3 do not mixed. According to some embodiments, when viewed in a plan view, the first to third emission areas PXA1 to OXA3 may be surrounded by the bank layers BK.

The bank layer BK may define the plurality of openings OP1, OP2 and OP3. When viewed in the second direction DR2, the openings OP1, OP2 and OP3 may be spaced apart from each other in the first direction DR1. The openings OP1, OP2, and OP3 may include the first opening OP1, the second opening OP2, and the third opening OP3 spaced apart from each other. The first opening OP1 may overlap the first light-emitting element OL1. The second opening OP2 may overlap the second light-emitting element OL2. The third opening OP3 may overlap the third light-emitting element OL3.

The light control units LCL may include a light conversion layer WCP and a light transmission layer LCP. The light conversion layer WCP may be located in the first and second openings OP1 and OP2. The light conversion layer WCP may be located on the encapsulation layer TFE. By way of example, the light conversion layer WCP may be located on the top surface of the first capping layer CP1.

The light conversion layer WCP may include a first light conversion layer WCP1 and a second light conversion layer WCP2. The first light conversion layer WCP1 may be located in the first opening OP1. The second light conversion layer WCP2 may be located in the second opening OP2. When viewed in the second direction DR2, the first light conversion layer WCP1 and the second light conversion layer WCP2 may be arranged in the first direction DR1. When viewed in the second direction DR2, the width of the second light conversion layer WCP2 may be greater than that of the first light conversion layer WCP1.

The first light conversion layer WCP1 may overlap the first emission area PXA1. The first light conversion layer WCP1 may overlap the first light-emitting element OL1. The second light conversion layer WCP2 may overlap the second emission area PXA2. The second light conversion layer WCP2 may overlap the second light-emitting element OL2.

The first light conversion layer WCP1 may include a first base resin BR1 and first quantum dots QD1 dispersed in the first base resin BR1. The second light conversion layer WCP2 may include a second base resin BR2 and second quantum dots QD2 dispersed in the second base resin BR2.

The cores of the quantum dots QD1 and QD2 included in the first light conversion layer WCP1 and the second light conversion layer WCP2 may be selected from among a group II-VI compound, a group III-VI compound, a group I-III-VI compound, a group III-V compound, a group IV-VI compound, a group IV element, a group IV compound, or any combinations thereof.

The group II-VI compound may be selected from a group consisting of: a binary compound selected from a group consisting of CdSe, CdTe, ZnS, ZnSe, ZnTe, ZnO, HgS, HgSe, HgTe, MgSe, MgS, and a mixture thereof; a ternary compound selected from a group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; or a quaternary compound selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound such as In₂S₃, In₂Se₃ or the like, a ternary compound such as InGaS₃, InGaSe₃ or the like, or an arbitrary combination thereof.

The group I-III-VI compound may be selected from among: a ternary compound selected from a group consisting of AgInS, AgInS₂, CuInS, CuInS₂, AgGaS₂, CuGaS₂ CuGaO₂, AgGaO₂, AgAlO₂ and a mixture thereof; or a quaternary compound among AgInGaS₂, CuInGaS₂ or the like.

The group III-V compound includes one selected from a group consisting of:

a binary compound selected from a group consisting of GaN, GaP, GaAs, GaSb, AlN, AlP, AlAs, AlSb, InN, InP, InAs, InSb, and a mixture thereof; a ternary compound selected from a group consisting of GaNP, GaNAs, GaNSb, GaPAs, GaPSb, AlNP, AlNAs, AlNSb, AlPAs, AlPSb, InNP, InNAs, InNSb, InPAs, InPSb, GaAlNP, and a mixture thereof; or a quaternary compound selected from a group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Meanwhile, the group III-V compound may further include a group II metal. For example, InZnP or the like may be selected as the group III-II-V compound.

The group IV-VI compound may be selected from a group consisting of: a binary compound selected from a group consisting of SnS, SnSe, SnTe, PbS, PbSe, PbTe, and a mixture thereof; a ternary compound selected from a group consisting of SnSeS, SnSeTe, SnSTe, PbSeS, PbSeTe, PbSTe, SnPbS, SnPbSe, SnPbTe, and a mixture thereof; or a quaternary compound selected from a group consisting of SnPbSSe, SnPbSeTe, SnPbSTe, and a mixture thereof. The group IV element may be selected from a group consisting of Si, Ge, and a mixture thereof. The group IV compound may be a binary compound selected from a group consisting of SiC, SiGe, and a mixture thereof.

Here, each element included in a multi-element compound, such as the binary compound, the ternary compound, and the quaternary compound, may exist in a particle with a uniform concentration or non-uniform concentration. That is, the chemical formula may mean the kinds of the elements included in the compound, and the atomic ratios in the compound may be different. For example, AgInGaS₂ may mean AgInxGa1—xS2 (where x is a real number from 0 to 1).

Meanwhile, the quantum dot may have a single structure in which the concentration of each element is uniform, or have a dual core-shell structure. For example, the material included in the core and the material included in the shell may be different from each other.

According to some embodiments, each of the quantum dots QD1 and QD2 may have the core-shell structure including nanocrystals. The shell of the quantum dot may serve as a protection layer for preventing or reducing chemical modification of the core to maintain the semiconductor characteristics and/or a charging layer for giving the electrophoretic characteristics to the quantum dot. The shell may be a single layer or a multilayer. The interface between the core and the shell may have a concentration gradient in which the concentration of elements present in the shell becomes reduced toward the core. By way of example, the shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO or the like, or a ternary compound such as MgAl₂O₄, CoFe₂O₄, NiFe₂O₄, CoMn₂O₄ or the like. However, the material is not limited thereto.

In addition, a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but the material is not limited thereto.

Here, each element included in a multi-element compound such as the binary compound or the ternary compound may exist in a particle with a uniform concentration or non-uniform concentration. That is, the chemical formula may mean the kinds of the elements included in the compound, and the atomic ratios in the compound may be different.

Each of the quantum dot QD1 and QD2 may have full width of half maximum (FWHM) of an emission wavelength spectrum of 45 nm (or about 45 nm) or less, preferably 40 nm (or about 40 nm) or less, and more preferably 30 nm (or about 30 nm) or less, and in this range, the color purity or color gamut may be relatively improved. In addition, the light emitted through such quantum dots QD1 and QD2 is emitted in all directions, thereby being capable of relatively improving the wide viewing angle.

The shape of each of the quantum dots QD1 and QD2 is one typically used in the art and not particularly limited. By way of example, a spherical, pyramidal, multi-arm, or cubic nano particle, a nano tube, a nanowire, a nano fiber, a nano-planar particle or the like may be used.

The color of the light emitted from each of the quantum dots QD1 and QD2 may be adjusted according to adjustment of the particle size or an element ratio in the compound, and thus the quantum dots QD1 and QD2 may have various emission colors such as blue, red, green, or the like. Therefore, the first quantum dots QD1 may convert first light provided by the first light-emitting element OL1 into second light having a different wavelength range from the first light. For example, the first quantum dots QD1 may convert the first light provided by the first light-emitting element OL1 into red light. Accordingly, the display device DD may output the red light through the first emission area PXA1.

The second quantum dots QD2 may convert first light provided by the second light-emitting element OL2 into third light having a different wavelength range from the first light. Here, the wavelength range of the second light may be different from that of the third light. For example, the second quantum dots QD2 may convert the first light provided by the second light-emitting element OL2 into green light. Accordingly, the display device DD may output the green light through the second emission area PXA2.

The second capping layer CP2 may be located on the top surface of the bank layer BK and the light conversion layer WCP. The first capping layer CP2 may cover the bank layer BK and the light conversion layer WCP. The second capping layer CP2 may be located in the third opening OP3. The second capping layer CP2 may cover the inner surfaces of the bank layer BK defining the third opening OP3. The second capping layer CP2 in the third opening OP3 may be located on the top surface of the first encapsulation layer CP1. As the first capping layer CP1 and the second capping layer CP2 cover the tops and bottoms the light conversion layer WCP and the bank layer BK, contaminants such as moisture or foreign matter entering into the light conversion layer WCP may be prevented or reduced.

The first capping layer CP1 and the second capping layer CP2 may include at least one inorganic layer. Namely, the first and second capping layers CP1 and CP2 may include inorganic materials. For example, the first capping layer CP1 and the second capping layer CP2 may be provided from silicon nitride, aluminum nitride, zirconium nitride, titanium nitride, halfnium nitride, tantalum nitride, silicon oxide, aluminum oxide, titanium oxide, zinc oxide, cerium oxide, or silicon oxide nitride, or a metal thin film in which the light transmittance is ensured. For example, the first capping layer CP1 may include silicon oxide nitride, and the second capping layer CP2 may include silicon oxide. However, the embodiments according to the present disclosure are not limited thereto. Meanwhile, the first and second capping layers CP1 and CP2 may further include organic layers. Each of the first and second capping layers CP1 and CP2 may be configured as a single layer or a plurality of layers.

The light transmission layer LCP may be located in the third opening OP3. The light transmission layer LCP may be located on the top surface of the second capping layer CP2. The light transmission layer LCP may overlap the third emission area PXA3. The light transmission layer LCP may overlap the third light-emitting element OL3.

When viewed in the second direction DR2, the first and light conversion layers WCP1 and WCP2 and the light transmission layer LCP may be arranged in the first direction DR1. When viewed in the second direction DR2, the width of the light transmission layer LCP in the first direction DR1 may be smaller than that of the first light conversion layer WCP1 in the first direction DR1. That is, when viewed in the second direction DR2, the second light conversion layer WCP2 may have the largest width, and the light transmission layer LCP may have the smallest width.

The light transmission layer LCP may include a third base resin BR3 and scattering agents SR dispersed in the third base resin BR3. The scattering agents SR may cause the light entering from the third light-emitting element OL3 into the light transmission layer LCP to be scattered in various directions. The scattering agents may be particles having a relatively greater density or specific gravity. By way of example, the scattering agents SR may include titanium oxide (TiOx), silica-based nanoparticles, or the like. The scattering agent SR may relatively improve the emission efficiency of light provided from the light-emitting element to pass through the light transmission layer LCP.

The light transmission layer LCP may transmit the first light provided from the third light-emitting element OL3. For example, the third light-emitting element OL3 may provide blue light to the light transmission layer LCP, and the blue light may pass through the light transmission layer LCP to be output towards the front direction of the display device DD. The light transmission layer LCP may be provided through the photolithography processes.

The spacer CS may be located on the top surface of the second capping layer CP2. The spacer CS may be located on the bank layer BK adjacent to the light transmission layer LCP. However, the embodiments according to the present disclosure are not limited thereto and the position of the spacer CS may be changed.

The spacer CS may protrude more towards the color filter panel UM than the bank layer BK. The thickness of the spacer CS may be in a range of 1.5 μm to 2.5 μm (or about 1.5 μm to about 2.5 μm). By way of example, the thickness of the spacer CS may be 2.4 μm (or about 2.4 μm).

The spacer CS may maintain the spacing between the light control member LCM and the color filter panel UM and the spacing between the display panel DP and the color filter panel UM. For example, the spacer CS may serve to maintain the cell gap (or the spacing) between the light control member LCM and the color filter panel UM or between the display panel DP and the color filter panel UM.

When viewed in the second direction DR2, the outer surface of the spacer CS may have a prescribed curvature. By way of example, when viewed in the second direction DR2, the spacer CS may have a partially elliptical shape. The outer surface of the spacer CS may be defined as the surface facing the color filter panel UM.

The spacer CS may include the same material as the light transmission layer LCP. The spacer CS may include the third base resin BR3 and the scattering agents SR. The spacer CS and the light transmission layer LCP may be simultaneously or concurrently (or substantially simultaneously or substantially concurrently) provided. The spacer CS and the light transmission layer LCP may be simultaneously or concurrently (or substantially simultaneously or substantially concurrently) provided through the lithography processes.

The filling member FL may be located between the display panel DP and the color filter panel UM. The filling member FL may be located between the light transmission member LCM and the color filter panel UM. The spacing between the light transmission member LCM and the color filter panel UM may be filled with the filling member FL. However, the embodiments according to the present disclosure are not limited thereto. The filling member FL may be omitted, and the color filter panel UM may be directly located on the color control member LCM.

The color filter panel UM may be located on the display panel DP. The color filter panel UM may be located on the light control member LCM. The color filter panel UM may be located on the filling member FL.

The color filter panel UM may include a second base substrate SUB2 (or the top substrate), a color filter layer CFL, and a low refractive layer LR. The color filter layer CFL and the low refractive layer LR may be sequentially laminated on the rear surface of the top substrate SUB2 in the third direction DR3. The rear surface of the top substrate SUB2 may be defined as a surface facing the top surface of the bottom substrate SUB1.

The top substrate SUB2 may include glass or a synthetic resin film. The synthetic resin layer may include a thermosetting resin. In particular, the synthetic resin layer may be a polyimide-based resin layer, but the material is not particularly limited. The synthetic resin layer may include at least one among an acrylic-based resin, a methacrylic-based resin, polyisoprene, a vinyl-based resin, an epoxy-based resin, a urethane-based resin, a cellulose-based resin, a siloxane-based resin, a polyamide-based resin, or a parylene-based resin. Besides, the top substrate SUB2 may include a glass substrate, a metal substrate, or an organic/inorganic composite material substrate, etc.

The color filter layer CFL may overlap the display area DA and transmit light optionally converted or transmitted by the light control units LCL. The color filter layer CFL may absorb light, having not been converted by but passed through the light control units LCL, to prevent the color purity of the display device DD (see FIG. 1) from being reduced. The color filter layer CFL may include color filters CF1, CF2, and CF3 including the same colors as the pixels. Due to this, the color filter layer CFL may filter external light to transmit the same colors as those of the pixels and thus the reflectivity of the external light may be reduced.

The color filter layer CFL may include may include a first color filter CF1, a second color filter CF2, and a third color filter CF3. The first to third color filters CF1, CF2, and CF3 may be arranged to respectively correspond to the first to third emission areas PXA1, PXA2, and PXA3 in a plan view. For example, the first color filter CF1 may be arranged to overlap the first emission area PXA1, the second color filter CF2 may be arranged to overlap the second emission area PXA2, and the third color filter CF3 may be arranged to overlap the third emission area PXA3.

Each of the first to third color filters CF1, CF2 and CF3 may include a base resin and a dye or a pigment dispersed in the base resin. Each of the first to third color filters CF1, CF2 and CF3 may transmit light in a specific wavelength range, and absorb most light in a wavelength range other than the specific wavelength range.

For example, the first color filter CF1 may include a red color filter. The second color filter CF2 may include a green color filter. The third color filter CF3 may include a blue color filter. The red color filter may transmit red light and absorb most of green light and blue light. The green color filter may transmit green light and absorb most of red light and blue light. The blue color filter may transmit blue light and absorb most of green light and blue light.

The first color filter CF1 may be located on the first light conversion layer WCP1. The first color filter CF1 may transmit second light provided from the light conversion layer WCP1. For example, the first light conversion layer WCP1 may convert first light provided from the first light-emitting element OL1 into red light, and the first color filter CF1 may transmit the red light provided from the first light conversion layer WCP1. The first color filter CF1 may absorb green light and blue light entering towards the first color filter CF1. The first color filter CF1 may absorb light, having not been converted by the first light conversion layer WCP1 in the light entering towards the first color filter CF1, to prevent the color purity from being reduced in the first emission area PXA1.

The second color filter CF2 may be located on the second light conversion layer WCP2 to transmit third light provided from the second light conversion layer WCP2. For example, the second light conversion layer WCP2 may convert the first light provided from the second light-emitting element OL2 into green light, and the second color filter CF2 may transmit the green light provided from the second light conversion layer WCP2. The second color filter CF2 may absorb red light and blue light entering towards the second color filter CF2. The second color filter CF2 may absorb light, having not been converted by the second light conversion layer WCP2 in the light entering towards the second color filter CF2, to prevent the color purity from being reduced in the second emission area PXA2.

The third color filter CF3 may be located on the light transmission layer LCP. The third color filter CF3 may overlap the light transmission layer LCP. The third color filter CF3 may transmit first light provided from the light-emitting element OL3 and passed through the light transmission layer LCP. For example, the third color filter CF3 may transmit blue light and absorb green light and red light to prevent the color purity from being reduced in the third emission area PXA3.

External light such as natural light may enter towards the display device DD from outside the display device DD. The external light may include red light, green light and blue light. If the display device DD does not include the color filter layer CFL, the external light entering towards the display device DD may be reflected by conductive patterns (e.g., the signal lines or electrodes, etc.) inside the display device DD to be provided to a user, and the user may view the reflected light.

The first to third color filters CF1, CF2 and CF3 may prevent or reduce reflection of the external light. For example, the first color filter CF1 may be a red color filter configured to absorb light corresponding to green light and blue light in the external light to filter the external light to transmit red light. In the same principle, the second color filter CF2 may be a green color filter configured to absorb light corresponding to red light and blue light in the external light to filter the external light to transmit the green light. The third color filter CF3 may be a blue color filter configured to absorb light corresponding to red light and green light in the external light to filter the external light to transmit the blue light.

The first and third color filters CF1 and CF3 may overlap each other in the non-emission area NPXA. The second color filter CF2 may not be located in the non- emission area NPXA. For example, the first and third color filters CF1 and CF3 may overlap each other along the third direction DR3 in the non-emission area NPXA. The third color filter CF3 may be located on the bottom surface of the top substrate SUB2, and the first color filter CF1 may be located under the third color filter CF3.

The first and third color filters CF1 and CF3 may overlap the bank layer BK in the non-emission area NPXA. The second color filter CF2 may not overlap the bank layer BK. The first and third color filters CF1 and CF3 arranged to overlap each other may block light from passing through the non-emission area NPXA to prevent or reduce color mixture between the first to third emission areas PXA1, PXA2 and PXA3.

The low refractive layer LR may be located under the color filter layer CFL. The low refractive layer LR may have a smaller refractive index than each of the light conversion layers WCP and the light transmission layer LCP. For example, the refractive index of the low refractive layer LR may be in a range of 1.1 to 1.5 (or about 1.1 to about 1.5), specifically 1.1 to 1.35 (or about 1.1 to about 1.35). However, the refractive index of the low refractive layer LR is not limited to the foregoing numeral examples. The low refractive layer LR may include a low refractive organic layer having a relative low refractive index. The low refractive layer LR may further include hollow particles and/or voids dispersed in the organic layer, and the refractive index of the low refractive layer LR may be adjusted by a ratio of the hollow particles and/or voids.

The refractive index of the low refractive layer LR located on the light control unit LCL may be used to re-enter light, which has not been converted by the light conversion layers WCP1 and WCP2 but output from the top surfaces of the light conversion layers WCP1 and WCP2, into the light conversion layers WCP1 and WCP2. The light re-entered into the light conversion layers WCP1 and WCP2 due to the low refractive layers LR may be converted by the quantum dots QD1 and QD2. Namely, the low refractive layer LR may serve to re-circulate the light using the refractive index to relatively improve the light emission efficiency of the display device DD.

The low refractive layer LR may include a material having a high light transmittance. For example, the low refractive layer LR may have a high transmittance of at least 90% (or about 90%). The high transmittance of the low refractive layer LR may not reduce the transmittance of light output towards the front surface of the display module DM.

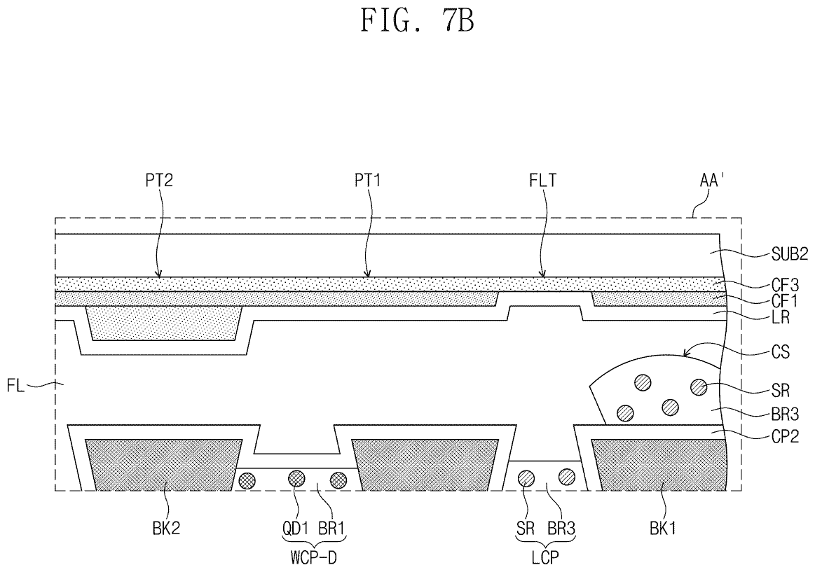

FIG. 7A is a cross-sectional view of a portion corresponding to line I-I′ illustrated in FIG. 1. FIG. 7B is an enlarged view of an AA' area illustrated in FIG. 7A.

FIG. 7A illustrates example cross sections of the display device DD corresponding to the non-display area NDA with the sealing member SAL located therein and the display area DA adjacent to the non-display area NDA.

By way of example, in FIG. 7A, the third light-emitting element OL3 and the light transmission layer LCP corresponding to the third emission area PXA3 located adjacent to the non-display area NDA are shown.

Overlapping descriptions of the components of FIG. 7A corresponding to those described with reference to the above drawings may be omitted or simplified.

Referring to FIG. 7A, the buffer layer BFL, the first insulation layer INS10 and the second insulation layer INS11 located on the top surface of the bottom substrate SUB1 may extend towards the non-display area NDA from the display area DA. The sealing member SAL according to some embodiments may be located on the top surface of the second insulation layer INS11 corresponding to the non-display area NDA. However, the embodiments according to the present disclosure are not necessarily limited thereto and may vary depending on the disposition of the insulation layers of the display panel DP. For example, the sealing member SAL may be located on the first insulation layer INS10 or contact the bottom substrate SUB1.

According to some embodiments, a portion of the conductive patterns of the circuit layer DP-CL may be located between the insulation layers in the non-display area NDA, and the conductive pattern may overlap the sealing member SAL in a plan view according to some embodiments.

The display panel DP may include a plurality of dams DAM1, DAM2, DAM3 and DAM4 located on the non-display area NDA. The plurality of dams DAM1, DAM2, DAM3 and DAM4 may be located on the bottom substrate SUB1. The dams DAM1, DAM2, DAM3 and DAM4 may be located on the second insulation layer INS11.

The dams DAM1, DAM2, DAM3 and DAM4 may include the first dam DAM1, the second dam DAM2, the third dam DAM3 and the fourth dam DAM4 arranged to be spaced apart from each other in one direction. The first dam DAM1 may be located closest to the display area DA among the dams DAM1, DAM2, DAM3 and DAM4. The fourth dam DAM4 may be located farthest from the display area DA. By way of example, four dams DAM1, DAM2, DAM3 and DAM4 are shown, but the number of dams is not limited thereto.

At least a portion of the dams DAM1, DAM2, DAM3 and DAM4 may have different laminate structures. For example, the first dam DAM1 may include the same material as the third insulation layer INS12. The second dam DAM2 may include a (1-1)-th layer P1-1 and a (1-2)-th layer P1-2 sequentially laminated along the third direction DR3. The third dam DAM3 may include a (2-1)-th layer P2-1 and a (2-2)-th layer P2-2 sequentially laminated along the third direction DR3. The fourth dam DAM4 may include a (3-1)-th layer P3-1 and a (3-2)-th layer P3-2 sequentially laminated along the third direction DR3. The (1-1)-th layer P1-1, the (2-1)-th layer P2-1 and the (3-1)-th layer P3-1 may include the same material as the third insulation layer INS12, and the (1-2)-th layer P1-2, the (2-2)-th layer P2-2 and the (3-2)-th layer P3-2 may include the same material as the pixel definition layer PDL.

The first dam DAM1, the (1-1)-th layer P1-1, the (2-1)-th layer P2-1 and the (3-1)-th layer P3-1 may be simultaneously or concurrently (or substantially simultaneously or substantially concurrently) provided in the third insulation layer INS12 providing processes, and the (1-2)-th layer P1-2, the (2-2)-th layer P2-2 and the (3-2)-th layer P3-2 may be simultaneously or concurrently (or substantially simultaneously or substantially concurrently) provided in the pixel definition layer PDL providing processes. However, the embodiments according to the present disclosure are not limited thereto, and the first to fourth dams DAM1, DAM2, DM3 and DAM4 may have the same material.

At least a portion of the plurality of dams DAM1, DAM2, DAM3 and DAM4 may have different heights in the third direction DR3. For example, the height of the first dam DAM1 may be lower than those of the second, third and fourth dams DAM2, DAM3 and DAM4. However, the embodiments according to the present disclosure are not limited thereto, and the heights of the first to fourth dams DAM1, DAM2, DM3 and DAM4 may have the same.

The first encapsulation layer EN1 of the encapsulation layer TFE may extend from the display area DA towards the non-display area NDA to be located on the plurality of dams DAM1, DAM2, DAM3 and DAM4. The first encapsulation layer EN1 of the encapsulation layer TFE may contact the plurality of dams DAM1, DAM2, DAM3 and DAM4. The first encapsulation layer EN1 may cover the first dam DAM1, the second dam DAM2 and the third dam DAM3. The first encapsulation layer EN1 may cover one of both sides, facing each other in the first direction DR1, of the fourth DMA4 and a portion of the top surface of the fourth dam DAM4. The other side and portion of the fourth dam DAM4 may be exposed outside from the first encapsulation layer EN1. One of both sides, facing each other in the first direction DR1, of the fourth DMA4 may be defined as a side adjacent to the display area DA.

The second encapsulation layer EN2 of the encapsulation layer TFE may be located on the first encapsulation layer EN1. The provision area of the second encapsulation layer EN2 including an organic layer may be divided by the dams DAM1, DAM2, DAM3 and DAM4. In a manufacturing process of the display panel DP, the second encapsulation layer EN2 having fluidity may flow towards the non-display area NDA and be blocked by one of the dams DAM1, DAM2, DAM3 and DAM4. By way of example, FIG. 7A illustrates the second encapsulation layer EN2 of which fluidity is blocked in a space between the first dam DAM1 and the second dam DAM2.

The third encapsulation layer EN3 may be located on the second encapsulation layer EN2 to cover the same. The third encapsulation layer EN3 may have the shape corresponding to the top surface of the second encapsulation layer EN2. The third encapsulation layer EN3 may extent more towards outside the non-display area NDA than the second encapsulation layer EN2. The third encapsulation layer EN3 may be located on the second dam DAM2 to block the flowing of the second encapsulation layer EN2 and on the third and fourth dams DAM3 and DAM4 arranged outer (or further out) than the second dam DAM2. The third encapsulation layer EN3 may contact the first encapsulation layer EN1 located on the second to fourth dams DAM2, DAM3 and DAM4, and encapsulate the second encapsulation layer EN2 together with the first encapsulation layer EN1. Accordingly, the second encapsulation layer EN2 may prevent or reduce transmission of contaminants such as moisture or oxygen thereto from the outside.

The dams DAM1, DAM2, DAM3 and DAM4 may be spaced apart from the sealing member SAL in a plan view. The dams DAM1, DAM2, DAM3 and DAM4 may prevent or reduce instances of the encapsulation layer TFE extending outside the non-display area NDA with the sealing member SAL located therein.

The light control member LCM may be located on the encapsulation layer TFE. The bank layer BK may be located on the encapsulation layer TFE. Hereinafter, a bank layer BK portion spaced apart from the non-display area NDA may be defined as a first bank layer BK1 and another bank layer BK portion located on the edge of the display area BA and adjacent to the non-display area NDA may be defined as a second bank layer BK2.

The light control member LCM may further include a dummy light conversion layer WCP-D. The dummy light conversion layer WCP-D may be arranged outer (or further out) than the light transmission layer LCP. The dummy light conversion layer WCP-D may be adjacent to the boundary between the display area DA and the non- edisplay area NDA. The dummy light conversion layer WCP-D may not overlap the light-emitting elements OL1, OL2 and OL3 (see FIG. 6).

When viewed in the second direction DR2, the dummy light conversion layer WCP-D may be accommodated in a dummy opening D-OP defined by the bank layer BK in an outer side than the light transmission layer LCP. By way of example, one dummy light conversion layer WCP-D is shown, but the number of the dummy light conversion layers WCP-D is not limited thereto.

By way of example, the dummy light conversion layer WCP-D may include the first base resin BR1 and the first quantum dots QD1, but is not limited thereto. The dummy light conversion layer WCP-D may include the second base resin BR2 and the second quantum dots QD2.

According to some embodiments, when the base resins BR1 and BR2 and the quantum dots QD1 and QD2 are provided to the light conversion layer WCP on the display panel DP through a nozzle, the nozzle may provide the base resins BR1 and BR2 and the quantum dots QD1 and QD2 to the dummy opening D-OP and then be moved in the first direction DR1. Here, when foreign matters are present in an ejection outlet of the nozzle, the foreign matters may be ejected to the dummy opening D-OP to be removed from the nozzle. Therefore, when the nozzle is moved towards the first and second openings OP1 and OP2 overlapping the light-emitting elements OL1 and OL2 (see FIG. 6) to provide the base resins BR1 and BR2 and the quantum dots QD1 and QD2, the amounts of the base resins BR1 and BR2 and the quantum dots QD1 and QD2 provided through each of the first and second openings OP1 and OP2 may be uniform.

Referring to FIGS. 7A and 7B, the color filter layer CFL may overlap the display area DA and the non-display area NDA. Hereinafter, and area in which a single color filter CF1, CF2 or CF3 among the first to third color filters CF1, CF2 and CF3 is located may be defined as a filter unit FLT. An area in which the first and third color filters CF1 and CF3 are laminated may be defined as a first area PT1. An area overlapping the display area DA and having the first to third color filters CF1, CF2 and CF3 laminated therein may be defined as a second area PT2. An area overlapping the non-display area NDA and having the first to third color filters CF1, CF2 and CF3 laminated therein may be defined as a dummy area D-CF.

The filter unit FLT may overlap the light-emitting elements OL1, OL2 and OL3 (see FIG. 6). By way of example, the filter unit FLT in FIG. 7A may overlap the third light-emitting element OL3. The first and second areas PT1 and PT2 may overlap the non-emission area NPXA. By way of example, the second area PT2 may arranged outer (or further out) than the first area PT1.

The first and second areas PT1 and PT2 may overlap the bank layer BK. By way of example, in FIG. 7A, the first area PT1 may overlap the first bank layer BK1 and the second area PT2 may overlap the second bank layer BK2.

The spacer CS may overlap the first area PT1. The spacer CS may be located on the first bank layer BK1. The spacer CS may be located on the first bank layer BK1 to maintain the cell gap between the light control member LCM and the color filter panel UM.

The second area PT2 may overlap the edge of the display area DA. The second area PT2 may overlap the second bank layer BK2. The second color filter CF2 of the second area PT2 may protrude more towards the light control member LCM than the surroundings. The second color filter CF2 of the second area PT2 may have the thickness in a range of 1.5 μm to 2.5 μm (or about 1.5 μm to about 2.5 μm). By way of example, the thickness of the second color filter CF2 may be 2.4 μm (or about 2.4 μm). The bottom surface of the second area PT2 facing the display panel DP may be more adjacent (or closer) to the display panel DP than the bottom surface of the first area PT1 facing the display panel DP. The spacing between the second bank BK2 and the second area PT2 may be smaller than that between the first bank BK1 and the first area PT1.

The second area PT2 may maintain the spacing between the light control member LCM and the color filter panel UM. For example, the second color filter CF2 of the second area PT2 may be protrude more than the surroundings to maintain the cell gap between the light control member LCM and the color filter panel UM.

When the plurality of spacers CS are located on the first bank layer BK1 and the second bank BK2, the spacer CS on the first bank layer BK1 may have a different thickness from the spacer CS on the second bank layer BK2. The light transmission layer LCP and the spacers CS may be simultaneously or concurrently (or substantially simultaneously or substantially concurrently) provided through the same processes. Here, it may not be easy to adjust the thicknesses of the spacer CS on the first bank layer BK1, the spacer CS on the second bank layer BK2 and the light transmission layer LCP.

For example, when changing the height of the light transmission layer LCP, the heights of the spacer CS on the first bank layer BK1 and the spacer CS on the second bank layer BK2 may be changed. When changing the height of the spacer CS on the first bank layer BK1, the heights of the light transmission layer LCP and the spacer CS on the second bank layer BK2 may be changed. When changing the height of the spacer CS on the second bank layer BK2, the heights of the light transmission layer LCP and the spacer CS on the first bank layer BK1 may be changed.

Furthermore, when the spacer CS located on the second area PT is thicker than a set thickness and the color filter panel UM is moved downwards due to the weight, the spacer CS contacting the color filter panel UM may be broken.

However, according to some embodiments of the present disclosure, the spacer CS may be located on the first bank layer BK1 and may not be located on the second bank layer BK2. The second area PT2 may be located on the second bank layer BK2. The second color filter CF2 of the second area PT2 may be provided through different processes from those of the spacer CS. Accordingly, it may be easy to adjust the thicknesses of the spacer CS and the light transmission layer LCP and the thickness of the color filter CF2 of the second area PT2.

By way of example, even when the thickness of the spacer CS is changed, the thickness of the color filter CF2 of the second area PT2 may not change. Even when the thickness of the color filter CF2 of the second area PT2 is changed, the thickness of the spacer CS may not change. Accordingly, it may be easy to manufacture the display device DD.

In addition, as the spacer CS and the second color filter CF2 of the second area PT2 are respectively provided in the preset thicknesses, the spacer CS and the color filter panel UM, and the second color filter CF2 and the light control member LCM may not contact each other even when the color filter panel UM is moved to the bottom due to the weight. Therefore, the spacer CS or the second color filter CF2 is prevented from being broken.

Referring to FIG. 7A, the dummy area D-CF may be located in the non- display area NDA. The dummy area D-CF may have a structure in which the first to third color filters CF1, CF2 and CF3 are laminated in the third direction DR3. For example, the first color filter CF1 may be located under the third color filter CF3, and the second color filter CF2 may be located under the first color filter CF1. The first to third color filters CF1, CF2 and CF3 arranged to overlap each other may prevent the dams DA1, DAM2, DAM3 and DAM4 of the display panel DP from being viewed.

By way of example, the thickness of the second color filter CF2 of the dummy area D-CF may be smaller than that of the second color filter CF2 of the second area PT2. However, this is merely an example, and the thickness of the second color filter CF2 is not limited thereto.

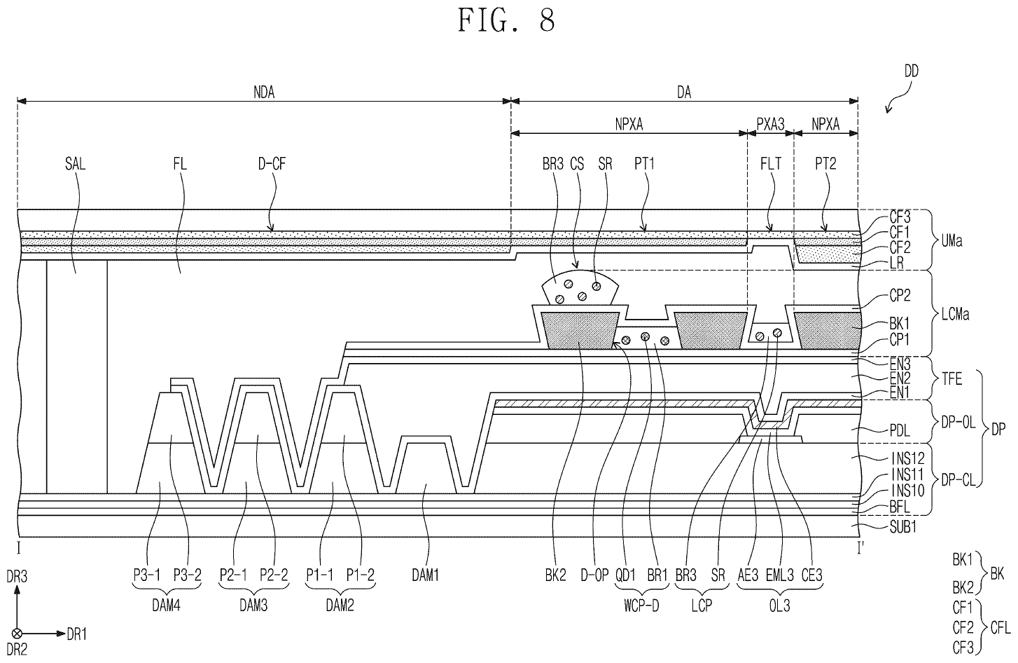

FIG. 8 is a cross-sectional view of a display device according to some embodiments of the present disclosure.

By way of example, FIG. 8 is a cross-sectional view of a portion corresponding to line I-I′ illustrated in FIG. 1.

By way of example, in FIG. 8, the third light-emitting element OL3 and the light transmission layer LCP corresponding to the third emission area PXA3 located adjacent to the non-display area NDA are shown.

Overlapping descriptions of components shown in FIG. 8 corresponding to those described with reference to the above drawings may be omitted or simplified.

Referring to FIG. 8, the first area PT1 may arranged outer (or further out) than the second area PT2. The first area PT1 may overlap the edge of the display area DA.

The first area PT1 may overlap the second bank layer BK2. The spacer CS may be located on the second bank layer BK2. The spacer CS may overlap the edge of the display area DA. The spacer CS may overlap the first area PT1. On the edge of the display area DA, the spacer CS may maintain the spacing between the light control member LCMa and the color filter panel UMa.

The second area PT2 may overlap the first bank layer BK1. The second color filter CF2 of the second area PT2 may be protrude more than the surroundings to maintain the spacing between the light control member LCMa and the color filter panel UMa.

As the spacer CS and the second color filter CF2 of the second area PT2 are provided through different processes, it may be easy to adjust the thicknesses of the spacer CS and the second color filter CF2 of the second area PT2.

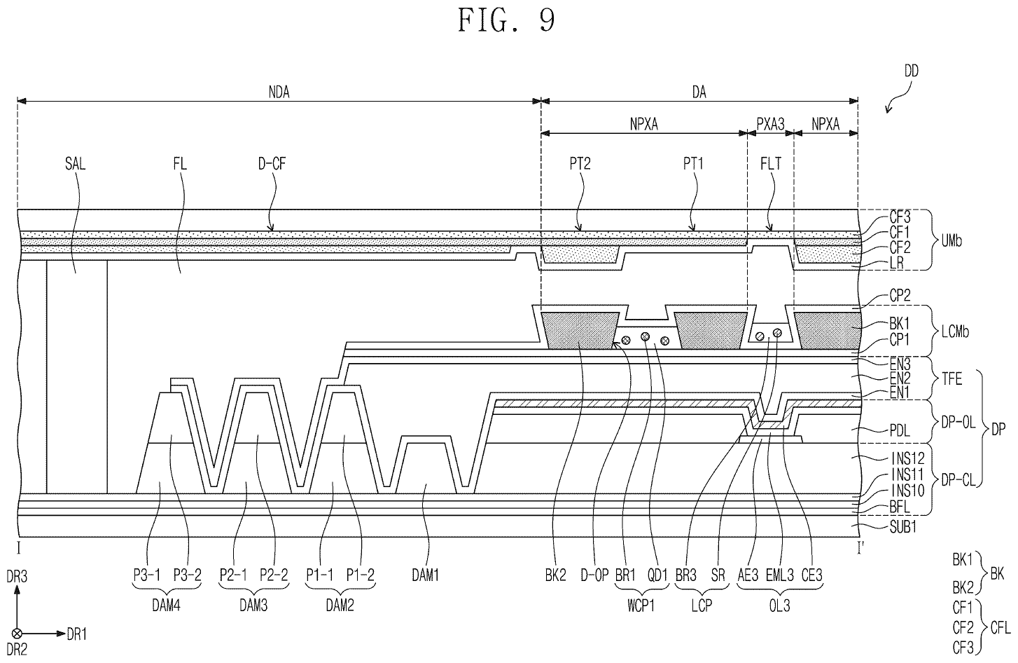

FIG. 9 is a cross-sectional view of a display device according to some embodiments of the present disclosure.

By way of example, FIG. 9 is a cross-sectional view of a portion corresponding to (e.g., along) the line I-I′ illustrated in FIG. 1.

By way of example, in FIG. 9, the third light-emitting element OL3 and the light transmission layer LCP corresponding to the third emission area PXA3 located adjacent to the non-display area NDA are shown.

Overlapping descriptions of components shown in FIG. 9 corresponding to those described with reference to the above drawings may be omitted or simplified.

Referring to FIG. 9, a plurality of second areas PT2 may overlap the first bank layer BK1 and the second bank layer BK2. The second color filter CF2 of the second area PT2 may maintain the spacing between the light control member LCMa and the color filter panel UMa.

The second color filter CF2 of the second area PT2 may be provided through different processes from those of the light transmission layer LCP. Accordingly, it may be easy to adjust the thicknesses of the second color filters CF2 and the light transmission layer LCP.

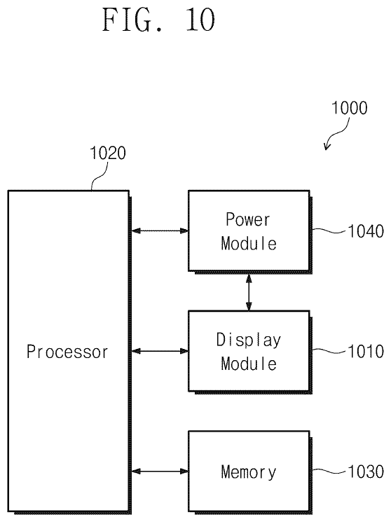

FIG. 10 is a block diagram illustrating an electronic device 1000 according to an embodiment of the present disclosure.

Referring to FIG. 10, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module which converts power supplied by the power supply module to generate power necessary for an operation of the electronic device 1000.

At least one of the components of the electronic device 1000 described above may be included in the display device DD according to embodiments described above. In addition, some of individual modules functionally included in one module may be included in the display device DD, and others may be provided separately from the display device DD. For example, the display device DD may include the display module 1010, and the processor 1020, the memory 1030, and the power module 1040 may be provided in form of other devices in the electronic device 1000 other than the display device DD.

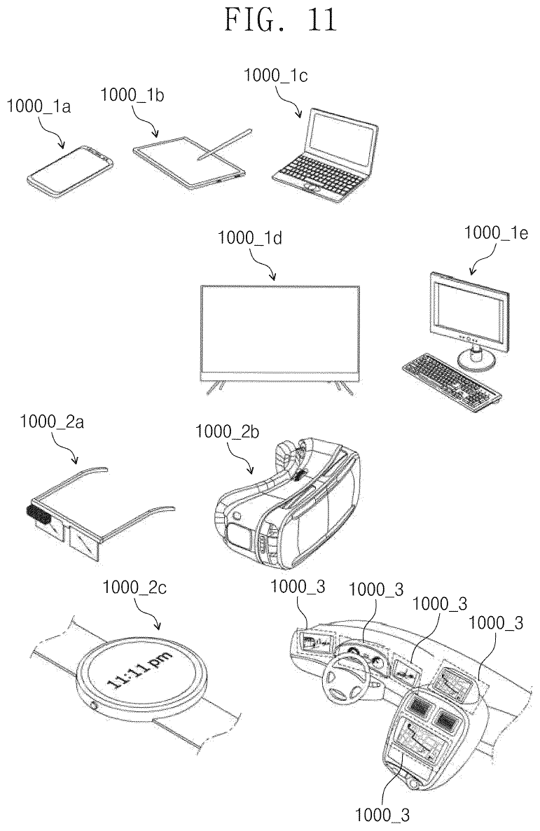

FIG. 11 is a schematic view of electronic devices according to embodiments of the present disclosure.

Referring to FIG. 11, various electronic devices to which the display device DD according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

According to the embodiments, the second color filter and the spacer maintaining a spacing between the display panel and the color filter panel may be provided in separate processes. Accordingly, it may be relatively easy to adjust the thicknesses of the spacer and the second filter. Thus, manufacturing the display device may be facilitated.

Although aspects of some embodiments of the present invention have been described, it is understood that the present invention should not be limited to these embodiments but various changes and modifications can be made by one ordinary skilled in the art within the spirit and scope of the present invention as hereinafter claimed. In addition, embodiments disclosed in the present disclosure are not intended to limit the technical spirit of the present disclosure, and the protection scope of the present invention should be interpreted based on the following appended claims, and their equivalents, and it should be appreciated that all technical spirits included within a range equivalent thereto are included in the protection scope of the present invention.

What is claimed is:

1. A display device comprising:
a display panel comprising a display area and a non-display area adjacent to the display area;
a light control member on the display panel and comprising a plurality of light control units, a bank layer configured to distinguish the light control units from each other, and a spacer on the bank layer; and
a color filter layer on the light control member and comprising a plurality of filter units each having a single color filter, a first area in which two color filters are laminated, and a second area in which three color filters are laminated,
wherein the spacer overlaps the first area.

2. The display device of claim 1, wherein the color filter layer comprises:
a first color filter configured to transmit first light;
a second color filter configured to transmit second light; and
a third color filter configured to transmit third light,
wherein the first area has a structure in which the first color filter and the third color filter are laminated, and
the second area has a structure in which the first to third color filters are laminated.

3. The display device of claim 2, wherein the filter units overlap the light control units, and the first and second areas overlap the bank layer.

4. The display device of claim 2, wherein among the first to third color filters of the second area, the first color filter is closer to the light control units than the third color filter and is more spaced apart from the light control units than the second color filter.

5. The display device of claim 2, wherein the color filter layer further comprises:
a dummy area on the non-display area and having a structure in which the first to third color filters are laminated, and
a thickness of the second color filter of the second area is greater than that of the second color filter of the dummy area.

6. The display device of claim 2, wherein a bottom surface of the second area facing the display panel protrudes more than a bottom surface of the first area facing the display panel.

7. The display device of claim 1, wherein the bank layer comprises:
a first bank layer adjacent to the light control units; and
a second bank layer overlapping an edge of the display area.

8. The display device of claim 7, wherein the first bank layer overlaps the first area, the second bank layer overlaps the second area, and the spacer is on the first bank layer.

9. The display device of claim 7, wherein the first bank layer overlaps the second area, the second bank layer overlaps the first area, and the spacer is on the second bank layer.

10. The display device of claim 1, wherein the display panel comprises:
a bottom substrate;
a circuit layer on the bottom substrate;
a light-emitting element layer on the circuit layer and comprising a plurality of light-emitting elements configured to emit first light; and
an encapsulation layer on the light-emitting element layer,
wherein the light control member is on the encapsulation layer.

11. The display device of claim 10, wherein the light control member comprises:
a light transmission layer configured to transmit the first light;
a first light conversion layer spaced apart from the light transmission layer and configured to convert the first light into second light; and
a second light conversion layer spaced apart from the light transmission layer and the first light conversion layer and configured to convert the first light into third light,
wherein the bank layer separates the light transmission layer, the first light conversion layer and the second light conversion layer from each other, and
wherein the light transmission layer comprises a same material as the spacer.

12. The display device of claim 11, wherein the light control member further comprises:
a first capping layer covering a bottom surface of the bank layer, a bottom surface of the first light conversion layer and a bottom surface of the second light conversion layer; and
a second capping layer covering a top surface of the bank layer, a top surface of the first light conversion layer and a top surface of the second light conversion layer.

13. The display device of claim 1, further comprising:
a low refractive layer covering a bottom surface of the color filter layer facing the light control member.

14. A display device comprising:
a display panel comprising a display area and a non-display area adjacent to the display area;
a light control member on the display panel and comprising a plurality of light control units and a bank layer configured to distinguish the light control units from each other; and
a color filter layer on the light control member and comprising a plurality of filter units each having a single color filter, a first area in which two color filters are laminated, and a second area in which three color filters are laminated,
wherein a bottom surface of the second area facing the display panel is more adjacent to the display panel than a bottom surface of the first area facing the display panel.

15. The display device of claim 14, wherein the color filter layer comprises:
a first color filter configured to transmit first light;
a second color filter configured to transmit second light; and
a third color filter configured to transmit third light,
wherein the first area has a structure in which the first color filter and the third color filter are laminated and
the second area has a structure in which the first to third color filters are laminated, and
wherein
the filter units overlap the light control units on the display area, and
the first and second areas overlap the bank layer on the display area.

16. The display device of claim 15, wherein the color filter layer further comprises a dummy area overlapping the non-display area and having a structure in which the first to third color filters are laminated, and
wherein a thickness of the third color filter of the second area is greater than that of the dummy area.

17. The display device of claim 15, further comprising:
a low refractive layer covering a bottom surface of the color filter layer facing the light control member.

18. An electronic device comprising
a display device, wherein the display device comprising,
a display panel comprising a display area and a non-display area adjacent to the display area;
a light control member on the display panel and comprising a plurality of light control units, a bank layer configured to distinguish the light control units from each other, and a spacer on the bank layer; and
a color filter layer on the light control member and comprising a plurality of filter units each having a single color filter, a first area in which two color filters are laminated, and a second area in which three color filters are laminated,
wherein the spacer overlaps the first area.

19. The electronic device of claim 18, wherein the color filter layer comprises:
a first color filter configured to transmit first light;
a second color filter configured to transmit second light; and
a third color filter configured to transmit third light,
wherein the first area has a structure in which the first color filter and the third color filter are laminated, and
the second area has a structure in which the first to third color filters are laminated.

20. The electronic device of claim 19, wherein the filter units overlap the light control units, and the first and second areas overlap the bank layer.
